(19) United States
(12) Patent Application Publication
(10) Pub. No.: US 2005/0287802 A1
(43) Pub. Date: Dec. 29, 2005

(54) Method for forming metal line in semiconductor memory device having word line strapping structure

(75) Inventors: Kwang-Ok Kim, Ichon-shi (KR); Yun-Seok Cho, Ichon-shi (KR)

Correspondence Address: MCDERMOTT WILL & EMERY LLP, 600 13TH STREET, N.W., WASHINGTON, DC, 20005-3096, US

(73) Assignee: Hynix Semiconductor, Inc., Ichon-shi (KR)

(21) Appl. No.: 11/019,740

(22) Filed: Dec. 23, 2004

(30) Foreign Application Priority Data
Jun. 25, 2004 (KR) 2004-48375

(51) Int. Cl. H01L 21/44

(52) U.S. Cl. 438/672

(57) ABSTRACT

The present invention relates to a method for forming a metal line in a semiconductor memory device having a word strapping structure. Especially, the metal line is formed by using a dual hard mask including a tungsten layer and a nitride layer as an etch mask. Also, the metal line includes at least more than one metal layer based on a material selected from titanium nitride and aluminum. Furthermore, for the formation of the dual hard mask, a photoresist pattern to which an ArF photolithography process and a KrF photolithography process are applicable is used. The method includes the steps of: forming a metal structure on a substrate; forming a dual hard mask on the metal structure; forming a photoresist pattern on the dual hard mask; patterning the dual hard mask by using the photoresist pattern as an etch mask; and patterning the metal structure by using the dual hard mask, thereby obtaining the metal line.

### FIELD OF THE INVENTION

The present invention relates to a method for fabricating a semiconductor memory device; and more particularly, to a method for forming a metal line in a semiconductor memory device having a word line strapping structure.

### DESCRIPTION OF RELATED ARTS

A word line strapping structure has been adopted in a double data rate (DDR) synchronous dynamic random access memory (SDRAM) device with 512 megabytes in order to meet the specifications for the design rule of 0.11 μm.

FIGS. 1A and 1B are micrographs of transmission electron microscopy (TEM) showing a conventional semiconductor memory device including various device elements.

As shown, there are word lines, sub-word lines, a metal line, bit lines, device isolation regions, and storage nodes denoted with ‘WL’, ‘SWD’, ‘ML’, ‘ISO’, and ‘SN’, respectively.

FIG. 1C is a micrograph of TEM showing a top view of a word line strapping area.

As shown in a marked region ‘A’, chips are arranged nearly in square form and have a specific structure obtained by partially widening a pattern at an Yᵢ-line of each bank, where i is a positive integer. This partially widened pattern structure is an 8F² cell structure having a cell efficiency of 61%.

FIGS. 2A and 2B are micrographs of TEM showing a sense amplifier area and sub-word line circuit region in a conventional semiconductor memory device having a word line strapping structure.

As shown, there are a sense amplifier area, metal lines, device isolation regions, bit lines, storage nodes, and word lines denoted with ‘S/A area’, ‘ML’, ‘ISO’, ‘BL’, ‘SN’, and ‘WL’, respectively.

The word line strapping structure is formed in an upper part of a cell region by having a pitch identical to that of the word line (WL) when metal lines (ML) are formed to reduce spaces between the sub-word lines (SWD) in a peripheral region. Therefore, instead of employing one approach of connecting an individual metal line with a corresponding bit line, strapping metal line contacts are formed between cell regions, so that each metal line can be connected with the corresponding gate structure through the respective strapping metal contact.

Because of this structural characteristic, it is necessary to proceed with an etching process for forming the metal lines in such a manner to pattern the metal lines with the same pitch of the gate structures, and this required condition brings out a problem in selectivity with respect to a photoresist pattern.

As the design rule for a semiconductor memory device has been increasingly scaled down, for a photolithography process using ArF of which wavelength is 193 nm in a semiconductor memory device with a line width of 0.1 μm, there is a serious problem in deformation of patterns because of a weak tolerance of an ArF photoresist to an etching process.

In order to overcome this limitation in the use of the ArF photoresist as an etch mask, a hard mask based on nitride is employed.

FIG. 3 is a cross-sectional view showing a stack structure for forming metal lines of a word line strapping structure by using nitride as a hard mask material.

As shown, a first titanium nitride (TiN) layer 301, an aluminum (Al) layer 302 and a second titanium nitride layer 303, a nitride layer 304 for use in a hard mask, an anti-reflective layer 305, and a photoresist pattern 306 are sequentially formed on a substrate 300.

Then, the anti-reflective coating layer 305 is etched by using the photoresist pattern 306 as an etch mask, and then, the nitride layer 304 is etched with use of the patterned anti-reflective coating layer 305 as an etch mask. Thereafter, the photoresist pattern 306 is removed. A metal stack structure M is obtained by patterning the first titanium nitride layer 301, the aluminum layer 302 and the second titanium nitride layer 303 by using the patterned nitride layer 304 as an etch mask. This metal stack structure M is formed as a metal line.

It is necessary to secure a predetermined thickness of the patterned nitride layer 304 which is used as a hard mask in order to have an intended selectivity during the etching process for forming the metal line M. Thus, during the etching process for forming the hard mask, there may be a line edge roughness (LER) problem typically arising when the ArF photoresist is employed.

FIG. 4 is a micrograph of TEM showing a semiconductor memory device with a word line strapping structure, wherein metal lines are formed by using a nitride-based hard mask.

As shown, even with the use of the nitride-based hard mask, the line edge roughness denoted as ‘X’ still appears in the metal lines.

In a semiconductor memory device having a minimum line width of 80 nm, an ArF photoresist having a thickness of 2000 Å is used, and this ArF photoresist has a poor etch selectivity compared with a deep ultraviolet (DUV) photoresist. Thus, it is not possible to proceed with a patterning process for forming a conventional metal line structure including a titanium nitride layer of 1000 A and an aluminum layer of 4000 Å by using the ArF photoresist.

However, in order to secure a sufficient surface resistance, these thicknesses of the metal layers should be maintained. For this reason, it is not possible to reduce the thickness of the conventional metal line structure.

### SUMMARY OF THE INVENTION

It is, therefore, an object of the present invention to provide a method for forming a metal line in a semiconductor memory device having a word line strapping structure capable of preventing an occurrence of line edge roughness in a photoresist during the metal line formation caused by a weak etch tolerance of the photoresist.

In accordance with one aspect of the present invention, there is provided a method for forming a metal line, including the steps of: forming a metal structure on a substrate; forming a dual hard mask on the metal structure; forming a photoresist pattern on the dual hard mask; patterning the dual hard mask by using the photoresist pattern as an etch mask; and patterning the metal structure by using the dual hard mask, thereby obtaining the metal line.

In accordance with another aspect of the present invention, there is provided a method for forming a metal line in a semiconductor memory device having a word line strapping structure, the method including the steps of: sequentially forming at least more than one metal layer, an insulation layer for forming a first sacrificial hard mask, a tungsten layer for forming a second sacrificial hard mask, and an anti-reflective coating layer on a substrate; forming a photoresist pattern on the anti-reflective coating layer; etching the anti-reflective coating layer by using the photoresist pattern as an etch mask; etching the tungsten layer with use of the photoresist pattern as an etch mask, thereby forming the first sacrificial hard mask; etching the insulation layer with use of the first sacrificial hard mask as an etch mask, thereby forming the second sacrificial hard mask; etching said at least more than one metal layer with use of the first and the second sacrificial hard masks, thereby forming a metal line; and removing the first and the second sacrificial hard masks.

### BRIEF DESCRIPTION OF THE DRAWINGS

The above and other objects and features of the present invention will become better understood with respect to the following description of the preferred embodiments given in conjunction with the accompanying drawings, in which:

FIG. 1A is a micrograph of transmission electron microscopy (TEM) showing a conventional semiconductor memory device including various device elements;

FIG. 1B is a micrograph of TEM showing a top view of conventional word lines and sub-word lines formed by employing a conventional method;

FIG. 1C is a micrograph of (TEM) showing a top view of a conventional word line strapping area;

FIGS. 2A and 2B are micrographs of TEM respectively showing a top view and a cross-sectional view of a sense amplifier area and sub-word line circuit region of a conventional semiconductor memory device having a word line strapping structure;

FIG. 3 is a cross-sectional view showing a conventional stack structure for forming a metal line of a word line strapping structure by using a nitride-based hard mask;

FIG. 4 is a micrograph of TEM showing a conventional semiconductor memory device having metal lines of a word line strapping structure formed by using the nitride-based hard mask shown in FIG. 3;

FIG. 5 shows a cross-sectional view of a stack structure for forming a metal line of a word line strapping structure by using a dual hard mask in accordance with a preferred embodiment of the present invention;

FIG. 6 is a micrograph of TEM showing a top view of metal lines formed by using a dual hard mask in accordance with the preferred embodiment of the present invention; and

FIGS. 7A to 7D are cross-sectional views illustrating a method for forming a metal line in a semiconductor memory device having a word line strapping structure with use of an ArF photolithography process in accordance with the preferred embodiment of the present invention.

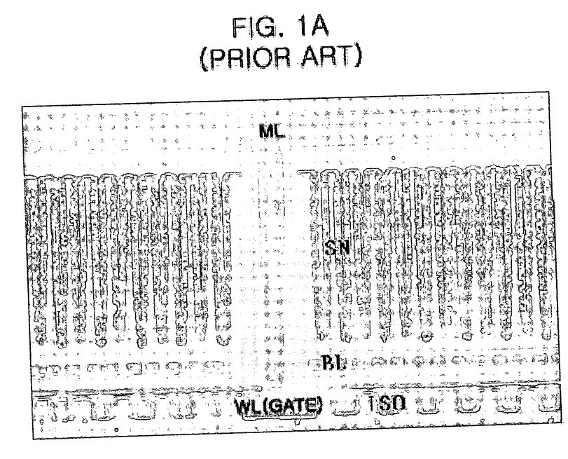

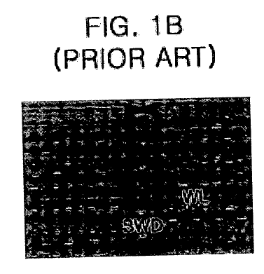

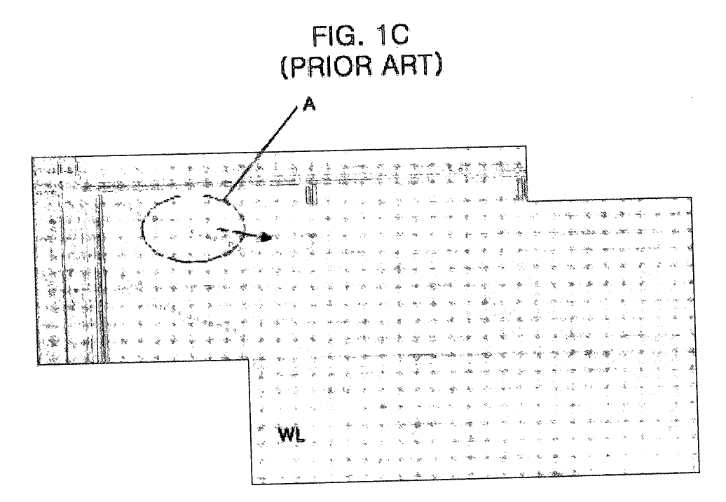

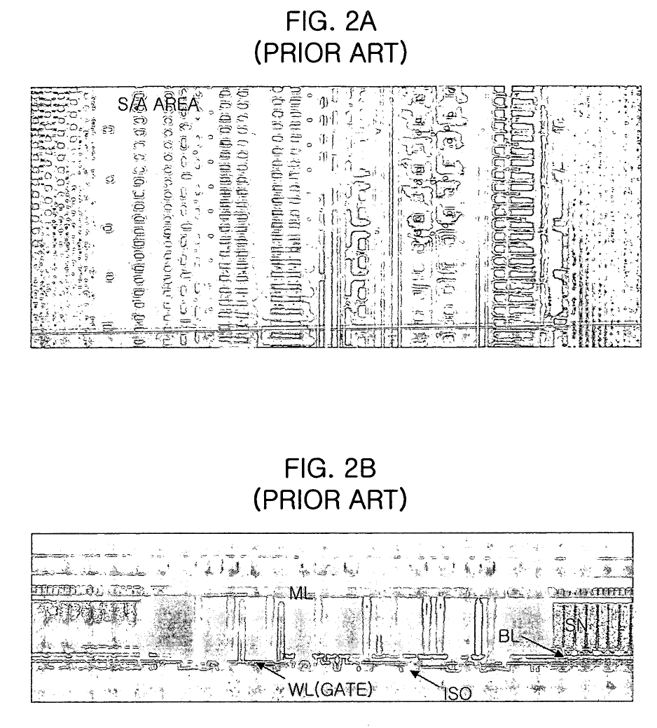

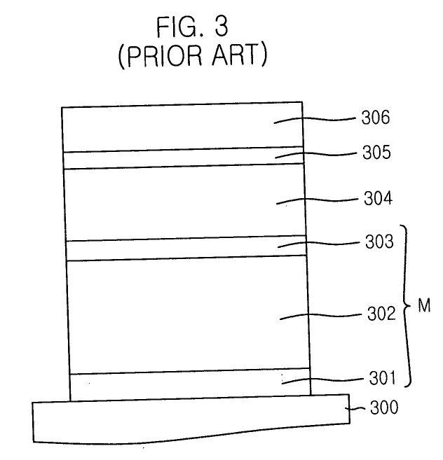

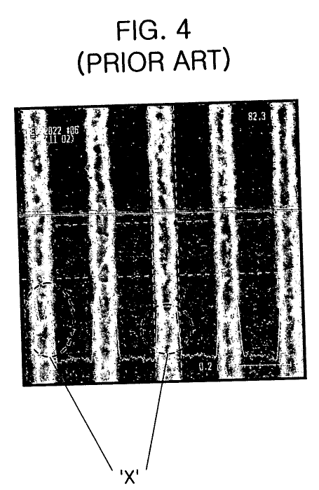

### DETAILED DESCRIPTION OF THE INVENTION

A method for forming a metal line in a semiconductor device having a word line strapping structure in accordance with a preferred embodiment of the present invention will be described in detail with reference to the accompanying drawings, which is set forth hereinafter.

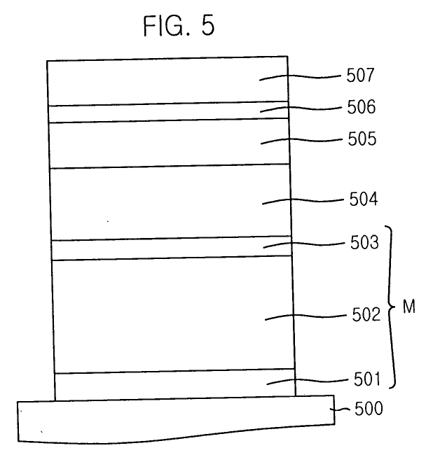

FIG. 5 is a cross-sectional view showing a stack structure for forming a metal line of a word line strapping structure by using a dual hard mask in accordance with the present invention.

As shown, a metal structure M, a dual hard mask and an anti-reflective coating layer 506 are sequentially formed on a substrate 500 provided with various device elements. Then, a photoresist pattern 507 is formed on the anti-reflective coating layer 506. Herein, the dual hard mask is provided with a tungsten layer 505 and a nitride layer 504. the metal structure M is obtained by sequentially forming a first titanium nitride (TiN) layer 501, an aluminum (Al) layer 502 and a second titanium nitride (TiN) layer 503.

The photoresist pattern 507 is used as an etch mask when the anti-reflective coating layer 506 is subjected to an etching process. With use of this patterned anti-reflective coating layer 506 as an etch mask, the tungsten (W) layer 505 is subsequently etched. Herein, a patterned tungsten layer 505 defines a region where a pattern will be formed. Afterwards, the photoresist pattern 507 is removed. In case of the incomplete removal of the photoresist pattern 507, a photoresist stripping process is additionally employed to completely remove the photoresist pattern 507. If the anti-reflective coating layer 506 is made of an organic material, the anti-reflective coating layer 506 is removed during the photoresist stripping process.

Next, the nitride layer 504 is subjected to another etching process by using the patterned tungsten layer 505 as an etch mask, whereby the patterned nitride layer 504 and the patterned tungsten layer 505 form the dual hard mask.

After the formation of the dual hard mask, the second titanium layer 503, the aluminum layer 502 and the first titanium layer 501 are etched by using the dual hard mask as an etch mask, thereby forming the metal structure M, i.e., a metal line.

The use of the dual hard mask solves the line edge roughness (LER) problem typically occurring when an ArF photoresist is employed in the course of forming a metal line.

FIG. 6 is a micrograph of transmitting electron microscopy (TEM) showing a top view of metal lines formed by using a dual hard mask of a tungsten layer and a nitride layer in accordance with the preferred embodiment of the present invention.

As shown, a plurality of metal lines ML are formed in line types, and each metal lines ML are free from the LER problem.

In accordance with the preferred embodiment of the present invention, there are provided two advantages. First, the use of the dual hard mask provides an effect of securing an etch selectivity of an ArF photoresist employed in an ArF photolithography process for forming metal lines. In the ArF photolithography process, approximately 2000 Å of the ArF photoresist is employed in the course of forming a gate structure with a line width of approximately 80 nm. On the other hand, in case of employing a deep ultraviolet (DUV) photoresist for forming the gate structure with the same design rule as above, approximately 8000 Å to approximately 9000 Å of the DUV photoresist is used. Herein, prior to performing the photolithography process, a portion of the DUV photoresist ranging from approximately 6000 Å to approximately 7000 Å is removed, and thus, the etch selectivity of the DUV photoresist becomes a serious problem. Therefore, the dual hard mask including the nitride layer and the tungsten layer is adopted to solve this problem. As described above, the nitride layer and the tungsten layer are patterned by using the ArF photoresist as an etch mask, thereby obtaining the dual hard mask. The subsequent etching process applied to the metal layers for forming the metal line proceeds by using a different etch selectivity between the dual hard mask and the metal layers for forming the metal line.

Second, the use of the tungsten layer as a part of the dual hard mask provides another effect. When the ArF photoresist is used to etch an oxide or nitride layer, the LER problem becomes severe in the ArF photoresist, and as a result, this LER problem propagates to the bottom layers disposed beneath the ArF photoresist. However, the use of the tungsten layer as the hard mask eliminates the LER generation in the ArF photoresist, thereby forming intact metal lines as shown in FIG. 6. Also, there is not a problem that a bottom part of the pattern becomes rounded and hung down, or a problem created because of residues. Accordingly, it is possible to improve reliability of semiconductor device operations.

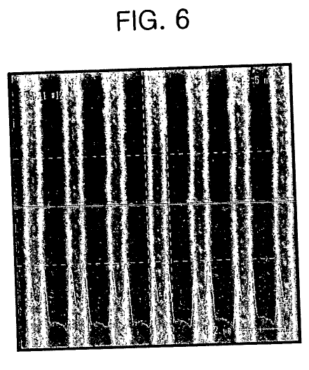

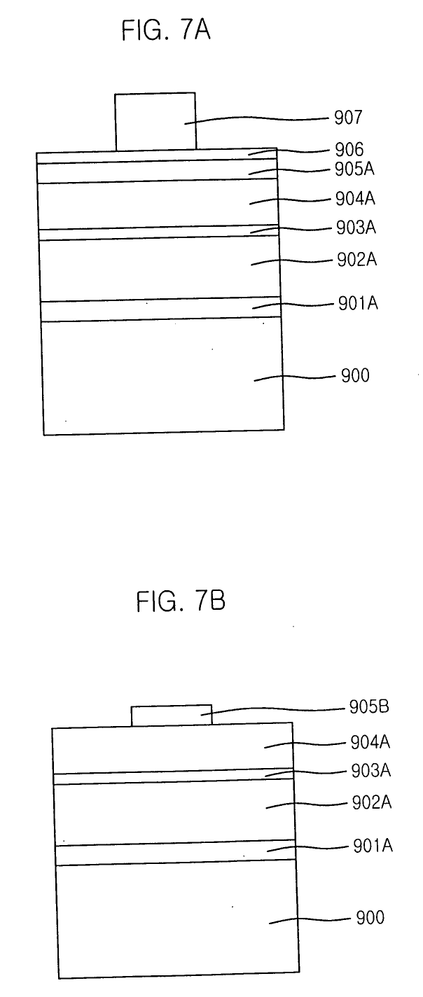

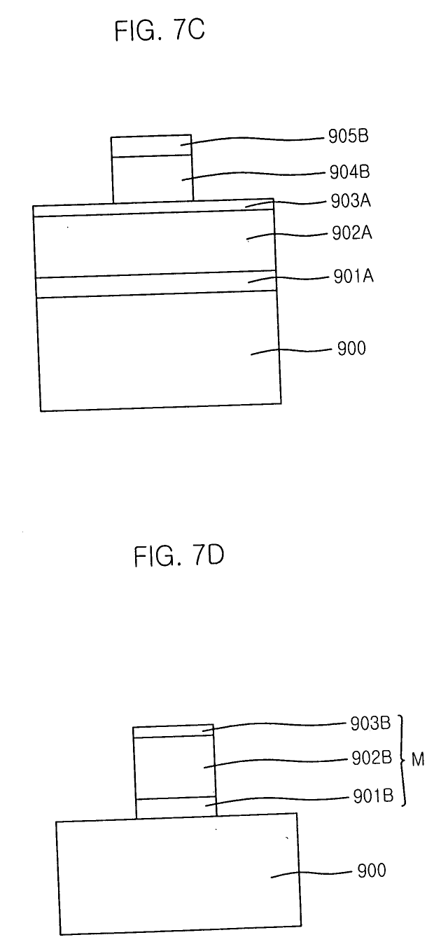

FIGS. 7A to 7D are cross-sectional views illustrating a method for forming a metal line in a semiconductor memory device having a word line strapping structure with use of an ArF photolithography process in accordance with the preferred embodiment of the present invention.

Referring to FIG. 7A, a first titanium layer 901A, an aluminum layer 902A, and a second titanium layer 903A are sequentially formed on a substrate 900 provided with various device elements. Herein, although the preferred embodiment of the present invention exemplifies a metal line structure by stacking the first titanium layer 901A, the aluminum layer 902A and the second titanium layer 903A, it is still possible to form the metal line structure with one single application of the above metal layers.

Subsequently, an insulation layer 904A for use in a first sacrificial hard mask and a tungsten layer 905A for use in a second sacrificial hard mask each having a predetermined thickness are sequentially formed on the second titanium nitride layer 903A through employing a physical vapor deposition (PVD) method or a chemical vapor deposition (CVD) method. Herein, the tungsten layer 905A for use in the second sacrificial hard mask is formed to supplement a weak etch tolerance of the insulation layer 904A for use in the first sacrificial hard mask. Also, the insulation layer 904A for use in the first sacrificial hard mask is made of nitride or oxide.

Next, an anti-reflective coating layer 906 is formed on the tungsten layer 905A, and then, an ArF photoresist is formed thereon until reaching a predetermined thickness. Afterwards, a photo-exposure process is performed to selectively photo-expose the ArF photoresist. At this time, although not illustrated, the photo-exposure process proceeds by employing a device using a light source of ArF and a predetermined reticle (not shown) for defining a width of a metal line to be formed. Subsequent to the photo-exposure process, a developing process makes photo-exposed or non-photo-exposed portions of the ArF photoresist remain. Thereafter, these photo-exposed or non-photo-exposed portions are removed by a cleaning process, thereby obtaining a photoresist pattern 907.

Herein, the anti-reflective coating layer 906 serves a role in preventing scattered reflection during the photo-exposure process and is preferably made of an organic material having a similar etch characteristic with the ArF photoresist. It is still possible to use an inorganic material for the anti-reflective coating layer 907.

Referring to FIG. 7B, the anti-reflective coating layer 906 is selectively etched by using the photoresist pattern 907 as an etch mask, thereby defining a region in which a pattern for forming a metal line will be formed. This first etching process for defining the pattern formation region with use of the photoresist pattern 907 as the etch mask has a greater impact on the pattern deformation. The reasons for this result are because the wavelength of the light source used in the photo-exposure process becomes shorter due to a trend of ultra micronization in semiconductor devices and thus, the transmittance depth of the light source becomes shallower, resulting in the thinner photoresist pattern 907, which subsequently weakens characteristics of the photoresist pattern 907 as an etch mask. Hence, the sacrificial hard mask is adopted to solve the above problem.

Meanwhile, since the ArF photoresist has a weak tolerance to a fluorine-based gas, the first etching process is performed by using a chlorine-based plasma in order to minimize the loss of the photoresist pattern 907.

At this time, a temperature of the substrate 900 is maintained in a range from approximately −10° C. to approximately 10° C. A preferable substrate temperature is approximately 0° C. It is also preferable to etch a partial portion of the tungsten layer 905A.

For the chlorine-based gas, such gases as Cl₂ and BCl₃ can be used. An inert gas such as argon (Ar) gas is preferably added to improve an etch profile and reproducibility of the intended etching process, and helium (He) gas can be additionally added to the inert gas. Therefore, the use of these special gases make it possible to reduce the loss of the photoresist pattern 907 compared with the use of hydrogen (H₂) gas and nitrogen (N₂) gas.

Next, the tungsten layer 905A for use in the second sacrificial hard mask is etched by using the photoresist pattern 907 and the anti-reflective coating layer 906 as an etch mask. From this second etching process, the above mentioned second sacrificial hard mask 905B is formed.

Meanwhile, since the photoresist pattern 907 and the anti-reflective coating layer 906 are also used as the etch mask for the second etching process, the chlorine-based plasma gas is used as like the first etching process. An amount of the etch gas and etch recipes are preferably controlled depending on a thickness of the tungsten layer 905A.

The photoresist pattern 907 and the anti-reflective coating layer 906 are automatically removed in the course of etching the tungsten layer 905A. In case that the photoresist pattern 907 and the anti-reflective coating layer 906 still remain, a photoresist stripping process typically performed after removing a hard mask is employed. Herein, a cleaning process performed each after the first etching process and the second etching process will not be described in detail. Also, because of the second sacrificial hard mask 905B, it is possible to prevent the line edge roughness appearing in the ArF photoresist from propagating to bottom layers.

Referring to FIG. 7C, the insulation layer 904A shown in FIG. 8B is etched by using the second sacrificial hard mask 905B as an etch mask, thereby obtaining the aforementioned first sacrificial hard mask 904B. Herein, there is provided a dual sacrificial hard mask structure including the first sacrificial hard mask 904B and the second sacrificial hard mask 905B.

Referring to FIG. 7D, the first titanium nitride layer 901A, the aluminum layer 902A and the second titanium nitride layer 903A shown in FIG. 8C are etched by using the second sacrificial hard mask 905B and the first sacrificial hard mask 904B as an etch mask, thereby obtaining a metal stack structure M including a patterned first titanium nitride layer 901B, a patterned aluminum layer 902B and a patterned second titanium nitride layer 903B. Herein, the metal stack structure M is formed as a metal line.

At this time, the dual sacrificial hard mask including the first sacrificial hard mask 904B and the second sacrificial hard mask 905B is removed by forming the first sacrificial hard mask 904B and the second sacrificial hard mask 905B each with a predetermined thickness that can be removed simultaneously after this third etching process, or by employing an additional etching process.

In accordance with the preferred embodiment of the present invention, the dual sacrificial hard mask including the tungsten-based sacrificial hard mask and the nitride-based sacrificial hard mask is used to form the metal line of the word line strapping structure having the same pitch as that of the gate structure. The use of the dual sacrificial hard mask provides effects of minimizing the pattern deformation and increasing process margins. As a result of these effects, it is possible to improve yields of semiconductor devices.

Also, although the preferred embodiment of the present invention exemplifies the case of employing the ArF photolithography process in the course of forming the metal line, it is still possible to employ a KrF photolithography process.

The present application contains subject matter related to the Korean patent application No. KR 2004-0048375, filed in the Korean Patent Office on Jun. 25, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

1. A method for forming a metal line, comprising the steps of:
forming a metal structure on a substrate;
forming a dual hard mask on the metal structure;
forming a photoresist pattern on the dual hard mask;
patterning the dual hard mask by using the photoresist pattern as an etch mask; and
patterning the metal structure by using the dual hard mask, thereby obtaining the metal line.

2. The method of claim 1, wherein the dual hard mask includes a tungsten layer and a nitride layer.

3. The method of claim 1, wherein the metal structure includes a single layer based on a material selected one of titanium nitride (TiN) and aluminum (Al).

4. The method of claim 1, wherein the metal structure includes stack layers of TiN and Al.

5. The method of claim 1, wherein the photoresist pattern is formed by employing an ArF photolithography process.

6. The method of claim 1, wherein the photoresist pattern is formed by employing a KrF photolithography process.

7. The method of claim 1, further including the step of forming an anti-reflective coating layer on the dual hard mask.

8. A method for forming a metal line in a semiconductor memory device having a word line strapping structure, the method comprising the steps of:
sequentially forming at least more than one metal layer, an insulation layer for forming a first sacrificial hard mask, a tungsten layer for forming a second sacrificial hard mask, and an anti-reflective coating layer on a substrate;
forming a photoresist pattern on the anti-reflective coating layer;
etching the anti-reflective coating layer by using the photoresist pattern as an etch mask;
etching the tungsten layer with use of the photoresist pattern as an etch mask, thereby forming the second sacrificial hard mask;
etching the insulation layer with use of the second sacrificial hard mask as an etch mask, thereby forming the first sacrificial hard mask;
etching said at least more than one metal layer with use of the first and the second sacrificial hard masks, thereby forming a metal line; and
removing the first and the second sacrificial hard masks.

9. The method of claim 8, wherein the insulation layer for forming the first sacrificial hard mask is made of a material selected from oxide and nitride.

10. The method of claim 8, further including the step of removing the photoresist pattern and the anti-reflective coating layer after the step of forming the first sacrificial hard mask.

11. The method of claim 8, wherein the anti-reflective coating layer is made of an organic material.

12. The method of claim 8, wherein said at least more than one metal layer is a single layer based on a material selected from titanium nitride (TiN) and aluminum (Al).

13. The method of claim 8, wherein said at least more than one metal layer includes stack layers of TiN and Al.

14. The method of claim 8, wherein the step of forming the photoresist pattern proceeds by employing an ArF photolithography process.

15. The method of claim 8, wherein the step of forming the photoresist pattern proceeds by employing a KrF photolithography process.
